(19) United States
(12) Patent Application Publication
(10) Pub. No.: US 2024/0290693 A1
(43) Pub. Date: Aug. 29, 2024

(54) SEMICONDUCTOR DEVICE

(71) Applicant: Rohm Co., Ltd., Kyoto-shi, Kyoto (JP)

(72) Inventor: Bin ZHANG, Kyoto-shi, Kyoto (JP)

(21) Appl. No.: 18/659,791

(22) Filed: May 9, 2024

Related U.S. Application Data
(63) Continuation of application No. PCT/JP2022/042404, filed on Nov. 15, 2022.

(30) Foreign Application Priority Data
Nov. 24, 2021 (JP) 2021-190267

(51) Int. Cl. H01L 23/495; H01L 23/31

(52) U.S. Cl. CPC H01L 23/4951; H01L 23/3107

(57) ABSTRACT

A semiconductor device A10 includes: a semiconductor element 30 having an element obverse surface 30a and an element obverse surface 30a faces away from each other in a z direction and including an electrode 34 formed on the element obverse surface 30a and an electrode terminal 36A in contact with the electrode 34 and protruding in the z direction; a lead 10A electrically connected to the semiconductor element 30 and having an obverse surface 101 and a reverse surface 102 faces away from each other in the z direction; and a sealing resin 40 covering the semiconductor element 30. The lead 10A includes a body 11 on a side toward the reverse surface 102 with respect to the obverse surface 101. The electrode terminal 36A has a bonding surface 365 facing the lead 10. The bonding surface 365 includes an overhanging portion 365a not overlapping with the body 11 as viewed in the z direction.

### TECHNICAL FIELD

The present disclosure relates to semiconductor devices.

### BACKGROUND ART

For a semiconductor device including a plurality of leads and a semiconductor element, flip-chip bonding of the semiconductor element has been proposed. One such a semiconductor device is disclosed, for example, in JP-A-2020-77694. The disclosed semiconductor device includes a plurality of leads, a semiconductor element, a bonding layer, and a sealing resin. The semiconductor element is mounted on the leads with a plurality of first electrodes facing the leads. Each first electrode includes a base electrically connected to a semiconductor layer, and a cylindrical pillar protruding from the base toward a lead. The pillar is bonded to the lead via a bonding layer. The leads are spaced apart from each other at least by a predetermined distance. The first electrodes to be bonded to different leads are formed at a separation distance corresponding to the distance between the leads. The greater the separation distance between the first electrodes is, the longer the current path formed in the semiconductor layer and thus the higher the electrical resistance of the current path.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1, with a sealing resin shown as transparent.

FIG. 3 is a plan view of the semiconductor device shown in FIG. 1, with a semiconductor element shown as transparent.

FIG. 4 is a bottom view of the semiconductor device shown in FIG. 1.

FIG. 5 is a front view of the semiconductor device shown in FIG. 1.

FIG. 6 is a rear view of the semiconductor device shown in FIG. 1.

FIG. 7 is a right-side view of the semiconductor device shown in FIG. 1.

FIG. 8 is a left-side view of the semiconductor device shown in FIG. 1.

FIG. 9 is a sectional view taken along line IX-IX in FIG. 3.

FIG. 10 is a sectional view taken along line X-X in FIG. 3.

FIG. 11 is a sectional view taken along line XI-XI in FIG. 3.

FIG. 12 is a partially enlarged view of FIG. 9.

FIG. 13 is a partially enlarged view of FIG. 9.

FIG. 14 is a partially enlarged sectional view of a semiconductor device according to a second embodiment of the present disclosure.

FIG. 15 is a partially enlarged sectional view of a semiconductor device according to a third embodiment of the present disclosure.

FIG. 16 is a partially enlarged sectional view of a semiconductor device according to a fourth embodiment of the present disclosure.

FIG. 17 is a partially enlarged sectional view of a semiconductor device according to a fifth embodiment of the present disclosure.

FIG. 18 is a partially enlarged sectional view of a semiconductor device according to a sixth embodiment of the present disclosure.

FIG. 19 is a plan view of a semiconductor device according to a seventh embodiment of the present disclosure, with a sealing resin and a semiconductor element shown as transparent.

FIG. 20 is a partially enlarged sectional view of a semiconductor device according to an eighth embodiment of the present disclosure.

### DETAILED DESCRIPTION OF EMBODIMENTS

The following describes preferred embodiments of the present disclosure in detail with reference to the accompanying drawings.

### First Embodiment

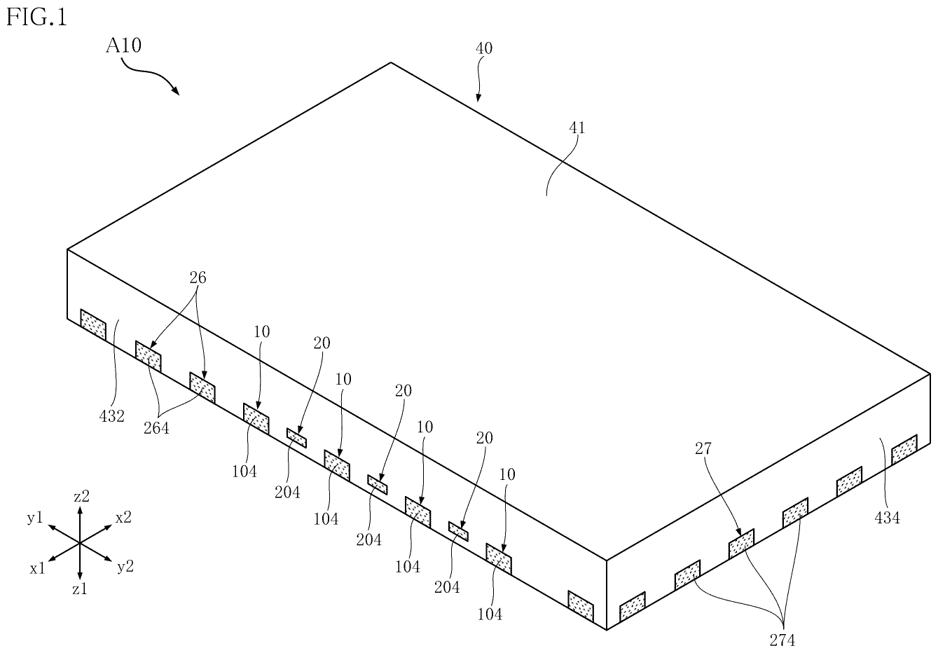

FIGS. 1 to 13 show an example of a semiconductor device according to the present disclosure. The semiconductor device A10 of the present embodiment includes a plurality of leads 10, a plurality of leads 20, a plurality of leads 25, a plurality of leads 26, a lead 27, a plurality of bonding portions 5, a plurality of metal layers 6, a semiconductor element 30, and a sealing resin 40. The semiconductor device A10 may be, but not limited to, a quad flat non-leaded (QFN) package as shown in FIG. 1. In addition, the applications and functions of the semiconductor device A10 are not limited. For example, the semiconductor device A10 can be used as a circuit element for a DC/DC converter.

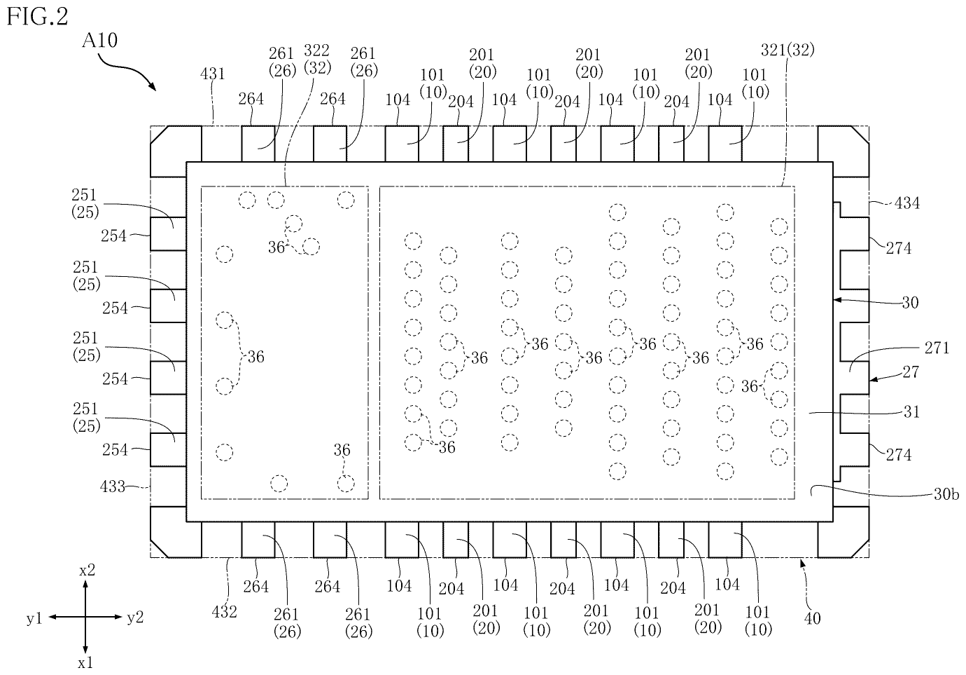

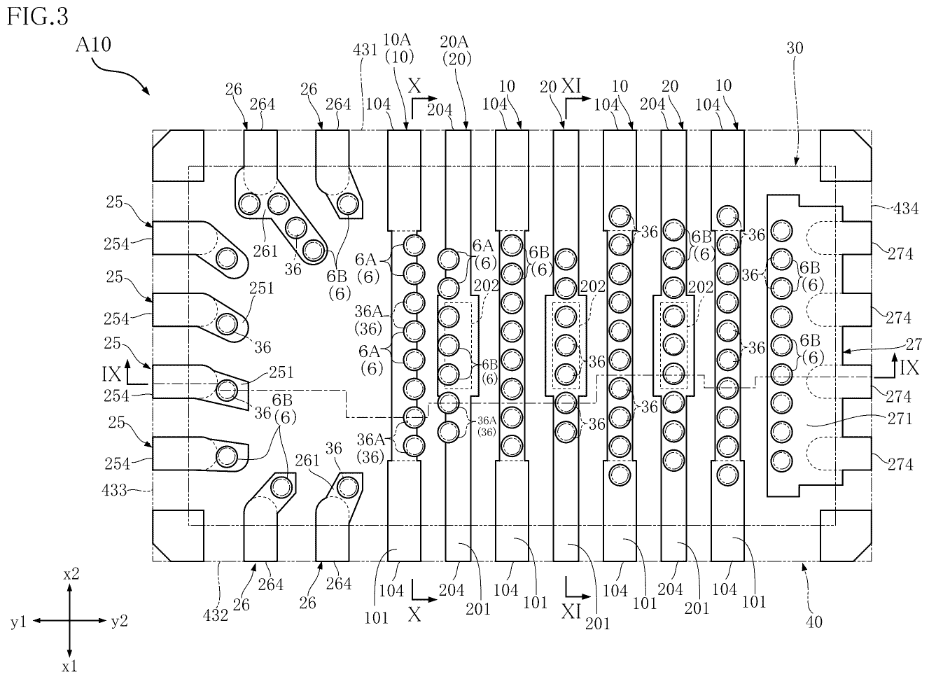

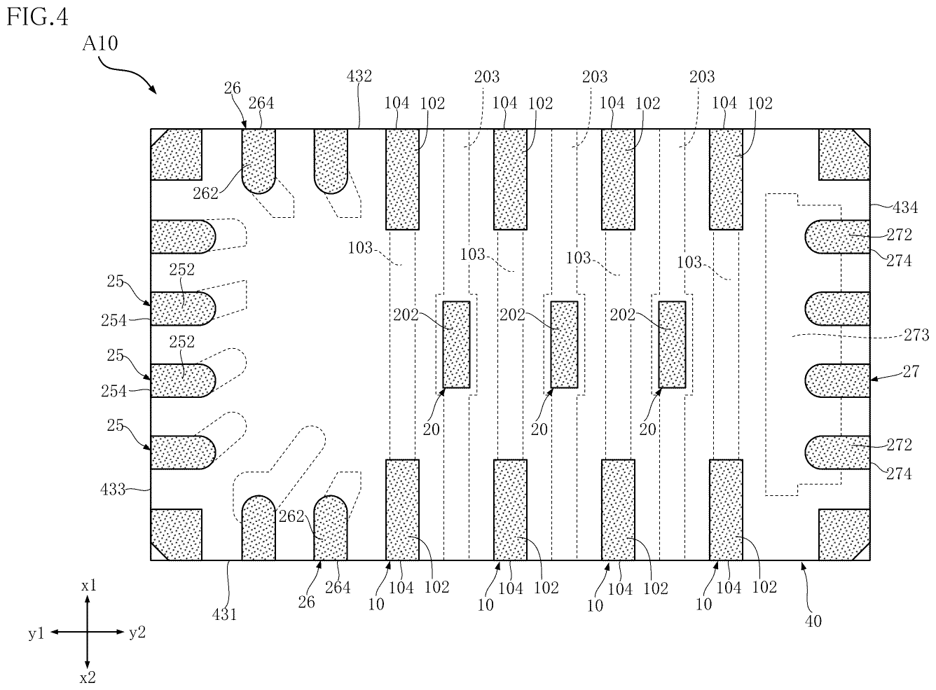

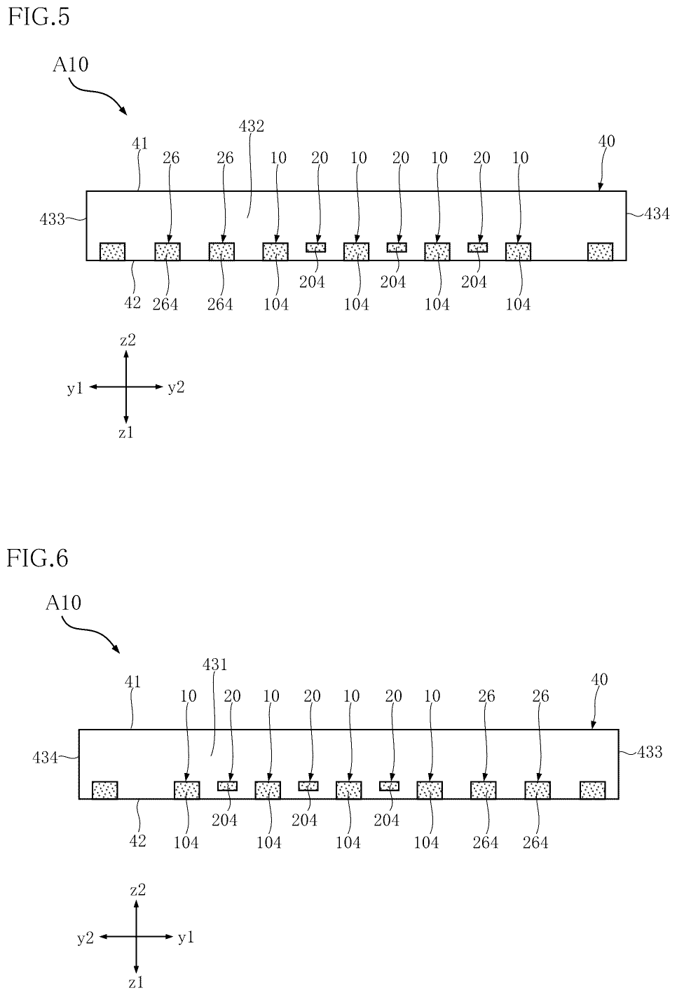

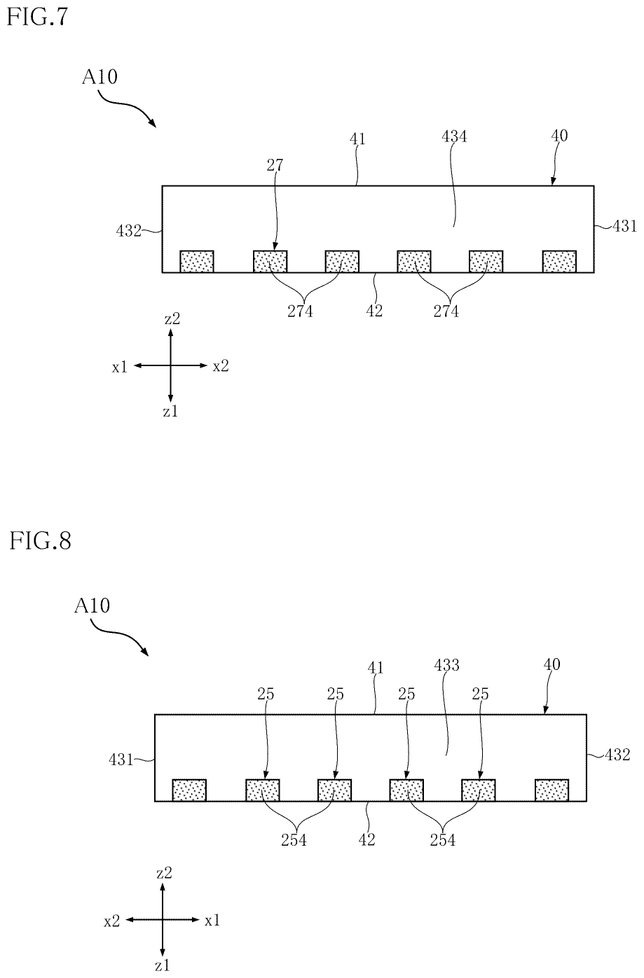

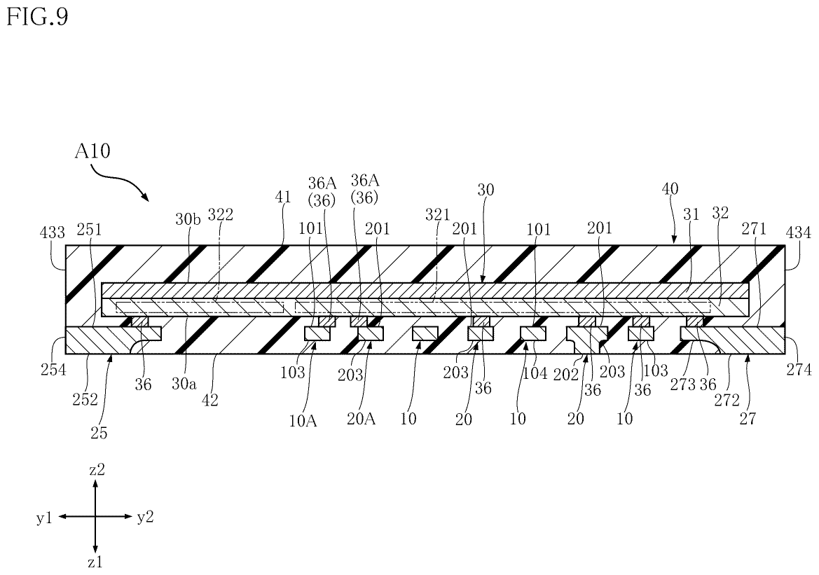

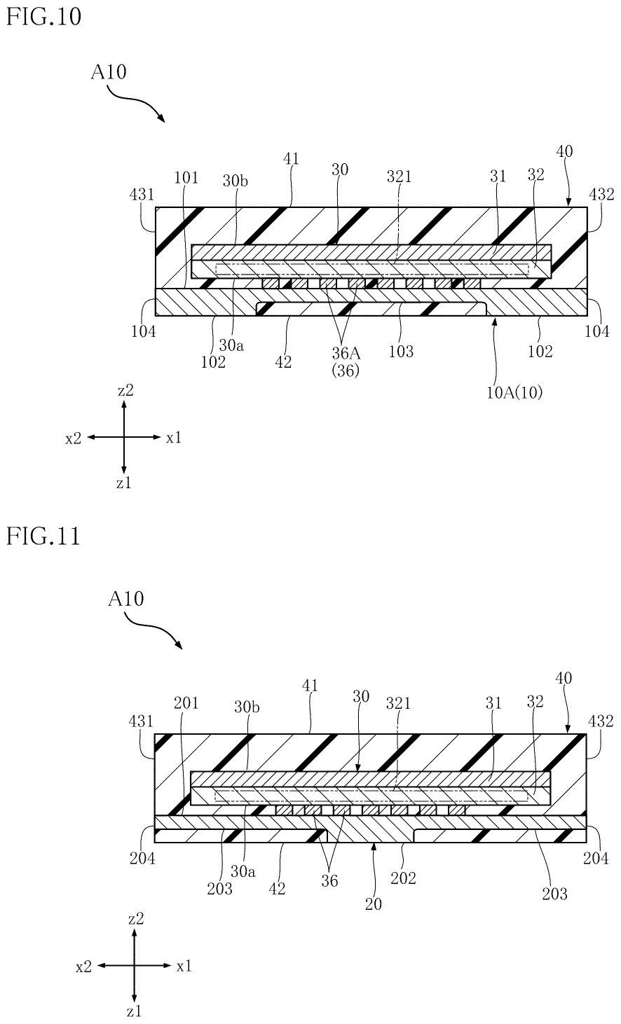

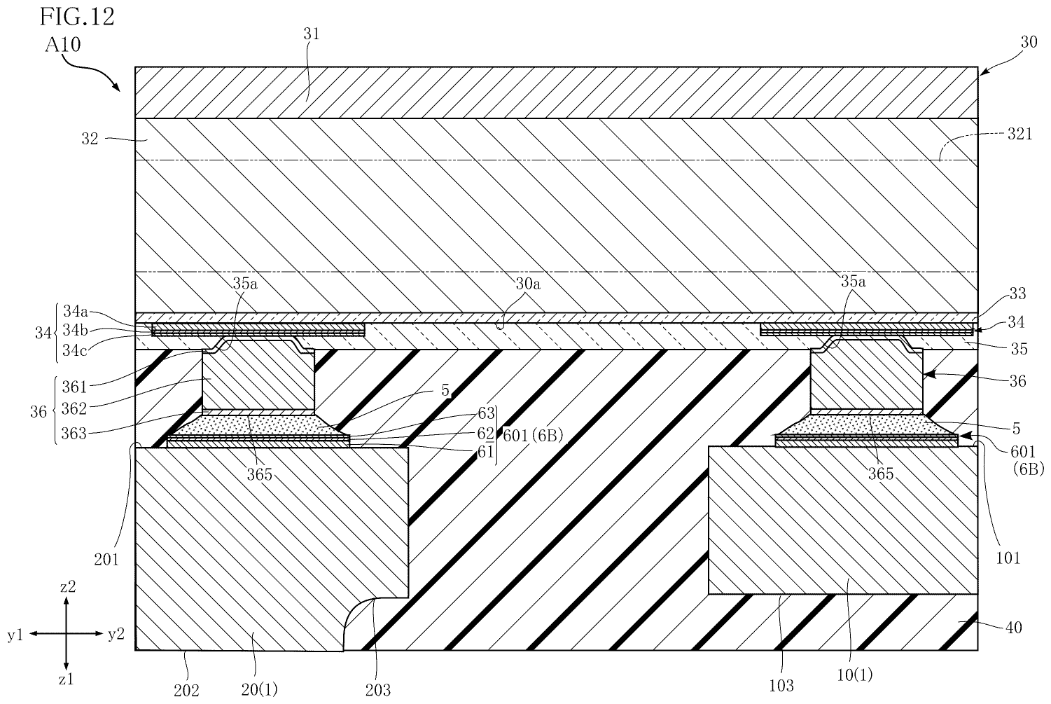

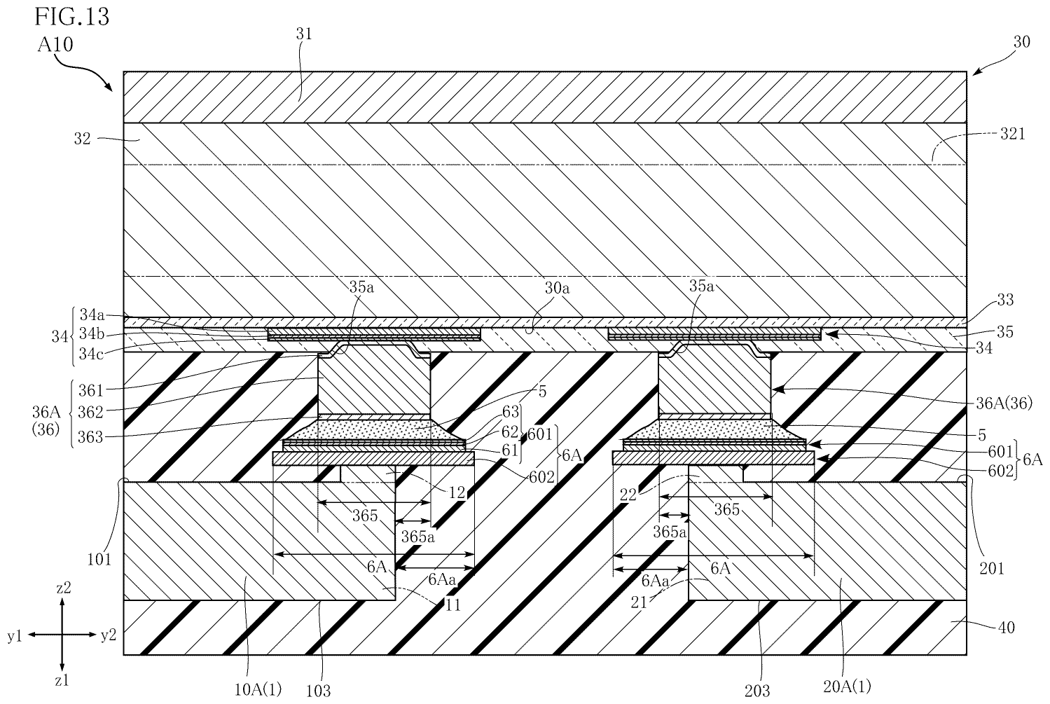

FIG. 1 is a perspective view of the semiconductor device A10. FIG. 2 is a plan view of the semiconductor device A10. For convenience, FIG. 2 shows the sealing resin 40 as transparent, and the outline of the sealing resin 40 is indicated by an imaginary line (two-dot-dash line). FIG. 3 is a plan view of the semiconductor device A10. For convenience, FIG. 3 shows the sealing resin 40 and the semiconductor element 30 as transparent, and the outlines of the sealing resin 40 and the semiconductor element 30 are indicated by imaginary lines (two-dot-dash lines). FIG. 4 is a bottom view of the semiconductor device A10. FIG. 5 is a front view of the semiconductor device A10. FIG. 6 is a rear view of the semiconductor device A10. FIG. 7 is a right-side view of the semiconductor device A10. FIG. 8 is a left-side view of the semiconductor device A10. FIG. 9 is a sectional view taken along line IX-IX in FIG. 3. FIG. 10 is a sectional view taken along line X-X in FIG. 3. FIG. 11 is a sectional view taken along line XI-XI in FIG. 3. FIG. 12 is a partially enlarged view of FIG. 9. FIG. 13 is a partially enlarged view of FIG. 9.

The semiconductor device A10 is in the form of plate and has the shape of an elongated rectangle as viewed in the thickness direction (in plan view). For convenience of description, an example of the thickness direction of the semiconductor device A10 (plan-view direction) is defined as the z direction, an example of the shorter side direction of the semiconductor device A10 orthogonal to the z direction (the vertical direction in FIGS. 2 to 4) is defined as the x direction, and an example of the direction orthogonal to the z direction and the x direction (the lateral direction in FIGS. 2 to 4) is defined as the y direction. Additionally, one side in the z direction (the lower side in FIGS. 5 to 8) is defined as the z1 side, the other side (the upper side in FIGS. 5 to 8) is defined as the z2 side. One side in the x direction (the lower side in FIGS. 2 and 3) is defined as the x1 side, the other side (the upper side in FIGS. 2 and 3) is defined as the x2 side. One side in the y direction (the left side in FIGS. 2 to 4) is defined as the y1 side, the other side (the right side in FIGS. 2 to 4) is defined as the y2 side. The z direction is an example of the “thickness direction” of the present disclosure. The shape and dimensions of the semiconductor device A10 are not limited.

The leads 10, 20, 25, 26, and 27 are spaced apart from each other. The leads 10, 20, 25, 26, and 27 support the semiconductor element 30 as shown in FIG. 2 and serve as terminals used for mounting the semiconductor device A10 on a wiring board. As shown in FIGS. 9 to 11, each of the leads 10, 20, 25, 26, and 27 is partly covered with the sealing resin 40. In FIGS. 1 and 4 to 8, the portions of the leads 10, 20, 25, 26, and 27 exposed from the sealing resin 40 are shaded with dots. In the following description, the leads 10, 20, 25, 26, and 27 may be collectively referred to as a “conductive member 1”.

For example, the conductive member 1 is formed out of a lead frame that is made by etching a metal plate. The processing employed for forming the conductive member 1 is not limited. The material of the conductive member 1 may be, but not limited to, Cu or a Cu alloy.

As shown in FIGS. 3 and 4, the plurality of (four in this embodiment) leads 10 extend in the x direction. The leads 10 are arranged at predetermined intervals in the y direction. The leads 10 are input terminals for receiving DC power (voltage) to be converted by the semiconductor device A10. The leads 10 are positive electrodes (P terminals).

As shown in FIGS. 9 and 10, each lead 10 has an obverse surface 101, two reverse surfaces 102, a recessed surface 103, and two end surfaces 104. The obverse surface 101 and the reverse surfaces 102 face away from each other in the z direction. The obverse surface 101 is oriented toward the z2 side in the z direction and faces the semiconductor element 30. The obverse surface 101 is covered with the sealing resin 40. Each lead 10 supports the semiconductor element 30 on the obverse e surface 101. The reverse surfaces 102 are oriented toward the z1 side in the z direction and are exposed from the sealing resin 40. As shown in FIG. 4, the two reverse surfaces 102 of each lead 10 are located at the opposite ends of the lead 10 in the x direction. The recessed surface 103 is located between the two reverse surfaces 102 in the x direction. In the z direction, the recessed surface 103 is located on the side toward the obverse surface 101 (toward the z2 side in the z direction) with respect to the reverse surface 102. The recessed surface 103 is covered with the sealing resin 40. In the present embodiment, each lead 10 has a width (a dimension in the y direction) that is greater at a portion where a reverse surface 102 is present than at a portion where the recessed surface 103 is present. The end surfaces 104 of each lead 10 are connected to both the obverse surface 101 and the reverse surface 102. One of the end surfaces 104 is located at the end of the lead 10 on the x1 side in the x direction, facing toward the x1 side in the x direction. The other end surface 104 is located at the end of the lead 10 on the x2 side in the x direction, facing toward the x2 side in the x direction. The respective end surfaces 104 are exposed from the sealing resin 40.

The plurality of leads 10 include a lead 10A. The lead 10A is the outermost one of the leads 10 on the y1 side in the y direction. As shown in FIG. 13, the lead 10A includes a body 11 and a protrusion 12. The body 11 is located on the side toward the reverse surface 102 (on the z1 side in the z direction) with respect to the obverse surface 101. The protrusion 12 protrudes from the obverse surface 101 toward the z2 side in the z direction. As viewed in z direction, the protrusion 12 overlaps with the bonding surfaces 365 of a plurality of electrode terminals 36, which will be described later.

As shown in FIGS. 3 and 4, the plurality of (three in this embodiment) leads 20 extend in the x direction. For this embodiment, the leads 20 are arranged at predetermined intervals in the y direction. Each lead 20 is located between two leads 10 adjacent in the y direction. The leads 10 and 20 are alternately arranged in the y direction. The leads 20 are used to output the AC power (voltage) converted by a later-described switching circuit 321 formed in the semiconductor element 30.

As shown in FIGS. 9 and 11, each lead 20 has an obverse surface 201, a reverse surface 202, a recessed surface 203, and two end surfaces 204. The obverse surface 201 and the reverse surface 202 face away from each other in the z direction. The obverse surface 201 is oriented toward the z2 side in the z direction and faces the semiconductor element 30. The obverse surface 201 is covered with the sealing resin 40. Each lead 20 supports the semiconductor element 30 on the obverse surface 201. The reverse surface 202 is oriented toward the z1 side in the z direction and is exposed from the sealing resin 40. As shown in FIG. 4, the reverse surface 202 is located at the center of the lead 20 in the x direction. As viewed in the y direction, the reverse surface 202 does not overlap with any of the reverse surfaces 102 of the leads 10. The recessed surface 203 surrounds the reverse surface 202 and reaches the opposite ends of the lead 20 in the x direction. In the z direction, the recessed surface 203 is located on the side toward the obverse surface 201 in the z direction (the z2 side in the z direction) with respect to the reverse surface 202. The recessed surface 203 is covered with the sealing resin 40. Each lead 20 has a width (a dimension in the y direction) that is greater at a portion where the reverse surface 202 is present than at a portion where the reverse surface 202 is not present. The end surfaces 204 of each lead 20 are connected to both the obverse surface 201 and the recessed surface 203. One of the end surfaces 204 is located at the end of the lead 20 on the x1 side in the x direction, facing toward the x1 side in the x direction. The other end surface 204 is located at the end of the lead 20 on the x2 side in the x direction, facing toward the x2 side in the x direction. The respective end surfaces 204 are exposed from the sealing resin 40.

The plurality of leads 20 include a lead 20A. The lead 20A is the outermost one of the leads 20 on the y1 side in the y direction and is adjacent to the lead 10A on the y2 side in the y direction. As shown in FIG. 13, the lead 20A includes a body 21 and a protrusion 22. The body 21 is located on the side toward the reverse surface 202 (on the z1 side in the z direction) with respect to the obverse surface 201. The protrusion 22 protrudes from the obverse surface 201 toward the z2 side in the z direction.

As shown in FIG. 3, the plurality of (four in this embodiment) leads 25 are located farther on the y1 side in the y direction than the lead 10A, specifically at the end of the semiconductor device A10 on the y1 side in the y direction. The leads 25 receive the power (voltage) for driving the later-described control circuit 322 and an electrical signal directed to the control circuit 322. As shown in FIGS. 3, 4, and 9, each lead 25 has an obverse surface 251, a reverse surface 252, and an end surface 254. The obverse surface 251 and the reverse surface 252 face away from each other in the z direction. The obverse surface 251 is oriented toward the z2 side in the z direction and faces the semiconductor element 30. The obverse surface 251 is covered with the sealing resin 40. Each lead 25 supports the semiconductor element 30 on the obverse surface 251. The reverse surface 252 is oriented toward the z1 side in the z direction and is exposed from the sealing resin 40. As shown in FIG. 4, the reverse surface 252 is located at the end of the lead 25 on the y1 side in the y direction. The end surface 254 is connected to both the obverse surface 251 and the reverse surface 252. The end surface 254 is located at the end of the lead 25 on the y1 side in the y direction, facing toward the y1 side in the y direction. The end surface 254 is exposed from the sealing resin 40. As shown in FIG. 8, the end surfaces 254 of the leads 25 are arranged at predetermined intervals in the x direction.

As shown in FIG. 3, the plurality of (four in this embodiment) leads 26 are located between the lead 10A and the plurality of leads 25 in the y direction. A subset (two in this embodiment) of the leads 26 are located at the end of the semiconductor device A10 on the x1 side in the x direction. The rest (two in this embodiment) of the leads 26 are located at the end of the semiconductor device A10 on the x2 side in the x direction. Each lead 26 receives, for example, an electrical signal directed to the control circuit 322. As shown in FIGS. 3 and 4, each lead 26 has an obverse surface 261, a reverse surface 262, and an end surface 264. The obverse surface 261 and the reverse surface 262 face away from each other in the z direction. The obverse surface 261 is oriented toward the z2 side in the z direction and faces the semiconductor element 30. The obverse surface 261 is covered with the sealing resin 40. Each lead 26 supports the semiconductor element 30 on the obverse surface 261. The reverse surface 262 is oriented toward the z1 side in the z direction and is exposed from the sealing resin 40. As shown in FIG. 4, the reverse surface 262 is located at the outer end of the lead 26 in the x direction. The end surface 264 is connected to both the obverse surface 261 and the reverse surface 262. The end surface 264 is located at the outer end of the lead 26 in the x direction, facing outward in the x direction. The end surface 264 is exposed from the sealing resin 40. As shown in FIGS. 5 and 6, the end surfaces 264 of the leads 26 are aligned in the y direction, along with the end surfaces 104 of the leads 10 and the end surfaces 204 of the leads 20.

As shown in FIG. 3, the lead 27 is located farther on the y2 side in the y direction than the leads 10. The lead 27 is an input terminal for receiving DC power (voltage) to be converted by the semiconductor device A10. The lead 27 is a negative electrode (N terminal). As shown in FIGS. 3, 4, and 9, the lead 27 has an obverse surface 271, a plurality of reverse surfaces 272, a recessed surface 273, and a plurality of end surfaces 274. The obverse surface 271 and each reverse surface 272 face away in the z direction. The obverse surface 271 is oriented toward the z2 side in the z direction and faces the semiconductor element 30. The obverse surface 271 is covered with the sealing resin 40. The lead 27 supports the semiconductor element 30 on the obverse surface 271. Each reverse surface 272 is oriented toward the z1 side in the z direction and is exposed from the sealing resin 40. As shown in FIG. 4, each reverse surface 272 is located at the end of the lead 27 on the y2 side in the y direction. The plurality of (four in this embodiment) reverse surfaces 272 are spaced apart from each other in the x direction at predetermined intervals in the x direction. The recessed surface 273 is located at a position on the lead 27 closer to the y1 side in the y direction. In the z direction, the recessed surface 273 is located on the side toward the obverse surface 271 (the z2 side in the z direction) from the reverse surface 272. The recessed surface 273 is covered with the sealing resin 40. The end surfaces 274 are connected to both the obverse surface 271 and one of the reverse surfaces 272. The end surfaces 274 are located at the end of the lead 27 on the y2 side in the y direction and faces toward the y2 side in the y direction. The end surfaces 264 are exposed from the sealing resin 40. As shown in FIG. 7, the end surfaces 274 are arranged at predetermined intervals in the x direction.

Optionally, plating of, for example, Sn may be applied to the reverse surfaces 102 and the end surfaces 104 of the leads 10, the reverse surfaces 202 and the end surfaces 204 of the leads 20, the reverse surfaces 252 and the end surfaces 254 of the leads 25, the reverse surfaces 262 and the end surfaces 264 of the leads 26, and the reverse surfaces 272 and the end surfaces 274 of the lead 27. Instead of the Sn plating, a plurality of metal layers may be applied in the order of Ni, Pd, and Au, for example. The numbers, shapes, and arrangement of the leads 10, 20, 25, 26, and 27 are not limited.

As shown in FIG. 2, the semiconductor element 30 is located at the center of the semiconductor device A10 as viewed in the z direction. As shown in FIGS. 9 to 11, the semiconductor element 30 is supported on the leads 10, 20, 25, 26, and 27. The semiconductor element 30 is covered with the sealing resin 40. The semiconductor element 30 includes a semiconductor substrate 31, a semiconductor layer 32, a passivation film 33, a plurality electrodes 34, an insulating layer 35, and a plurality of electrode terminals 36. The semiconductor element 30 is a flip-chip LSI formed with an internal circuit.

The semiconductor element 30 is elongated rectangular as viewed in the z direction as shown in FIG. 2 and is in the form of plate as shown in FIGS. 9 to 11. The semiconductor element 30 has an element obverse surface 30a and an element reverse surface 30b. The element obverse surface 30a faces the obverse surfaces 101 of the leads 10, the obverse surfaces 201 of the leads 20, the obverse surfaces 251 of the leads 25, the obverse surfaces 261 of the leads 26, and the obverse surface 271 of the lead 27 in the z direction. The element reverse surface 30b faces away from the element obverse surface 30a in the z direction.

As shown in FIGS. 12 and 13, on the z1 side in the z direction of semiconductor the substrate 31, the semiconductor layer 32, the passivation film 33, the electrodes 34, the insulating layer 35, and the electrode terminals 36 are disposed. The semiconductor substrate 31 is made of silicon (Si) or SiC (silicon carbide), for example. In the present embodiment, the surface of the semiconductor substrate 31 on the z2 side in the z direction forms the element reverse surface 30b.

As shown in FIGS. 9 to 13, the semiconductor layer 32 is stacked on the z1 side of the semiconductor substrate 31 in the z direction. The semiconductor layer 32 contains a plurality of p-type and n-type semiconductors obtained by doping different elements. The semiconductor layer 32 includes a switching circuit 321 and a control circuit 322 that is electrically connected to the switching circuit 321. The switching circuit 321 includes a plurality of switching elements, such as metal-oxide-semiconductor field-effect transistors (MOSFETs) or insulated gate bipolar transistors (IGBTs). For the semiconductor device A10 of this example, the switching circuit 321 is divided into two regions, which are a high voltage region (upper arm circuit) and a low voltage region (lower arm circuit). Each region includes n-channel MOSFETs, for example. The control circuit 322 includes a gate driver for driving the switching circuit 321 and a bootstrap circuit for the high-voltage region of the switching circuit 321 and controls the switching circuit 321 for operating normally. The semiconductor layer 32 additionally includes a wiring layer (not shown). The wiring layer electrically connects the switching circuit 321 and the control circuit 322 to each other.

As shown in FIGS. 12 and 13, the passivation film 33 covers the surface of the semiconductor layer 32 on the z1 side in the z direction. The passivation film 33 is electrically insulating. The passivation film 33 is composed of a film of silicon oxide (Sid₂) disposed in contact with the semiconductor layer 32 and a film of silicon nitride (Si₃N₄) disposed in contact with the silicon oxide film. In the present embodiment, the surface of the passivation film 33 on the z1 side in the z direction forms the element obverse surface 30a.

The electrodes 34 are formed on the element obverse surface 30a. The shape of each electrode 34 as viewed in the z direction is not limited, and the arrangement of the electrodes 34 are not limited. Each electrode 34 is connected to the wiring layer formed in the semiconductor layer 32 through an opening (not shown) formed in the passivation film 33. Thus, each electrode 34 is electrically connected to either the switching circuit 321 or the control circuit 322 formed in the semiconductor layer 32. As shown in FIGS. 12 and 13, each electrode 34 is electrically connected to the conductive member 1 via an electrode terminal 36. In the present embodiment, each electrode 34 is composed of plurality of metal layers, including a first layer 34a, a second layer 34b, and a third layer 34c sequentially deposited on the z1 side of the passivation film 33 in the z direction. The first layer 34a in contact with the passivation film 33 is made of Cu. The second layer 34b in contact with the first layer 34a is made of Ni. The third layer 34c in contact with the second layer 34b is made of Pd. The configuration of the electrodes 34 is not limited.

As shown in FIGS. 12 and 13, the insulating layer 35 is formed on the element obverse surface 30a and partly covers the passivation film 33 and the electrodes 34. The insulating layer 35 is electrically insulating. In this embodiment, the insulating layer 35 is made of a phenolic resin, but the material of the insulating layer 35 is not limited to this. For example, the insulating layer 35 may be made of a different insulating material, such as a polyimide resin. The insulating layer 35 has a plurality of openings 35a through each of which an electrode 34 is exposed. The insulating layer 35 can be formed by applying a photosensitive resin material with a spin coater, followed by photolithography.

As shown in FIGS. 9 to 11, the electrode terminals 36 are disposed on the element obverse surface 30a and protrude toward the conductive member 1. As shown in FIGS. 12 and 13, each electrode terminal 36 is connected to one of the electrodes 34 through an opening 35a formed in the insulating layer 35. As viewed in the z direction, each electrode terminal 36 has a central portion in contact with the corresponding electrode 34 and a peripheral portion overlapping with the insulating layer 35. The electrode terminals 36 are electrically conductive.

As shown in FIGS. 12 and 13, each electrode terminal 36 includes a seed layer 361, a first plating layer 362, and a second plating layer 363. The seed layer 361 is in contact with the corresponding electrode 34 and the insulating layer 35 and contains Cu. The seed layer 361 is formed by electroless plating, for example. The material and method for forming the seed layer 361, however, are not limited. For example, the seed layer 361 may be formed by sputtering. The first plating layer 362 is deposited on the seed layer 361 and made of Cu or a Cu alloy, for example. The first plating layer 362 is formed by electroplating. The material of the first plating layer 362 is not limited. The second plating layer 363 is deposited on the first plating layer 362. The second plating layer 363 is interposed between the first plating layer 362 and a bonding portion 5 and serves to inhibit chemical reaction between the first plating layer 362 and the bonding portion 5. The second plating layer 363 is made of a metal suitable for inhibiting the chemical reaction. Examples such metals include, but not limited to, Ni and Fe. In the present embodiment, since the first plating layer 362 contains Cu and the bonding portion 5 contains Sn, the second plating layer 363 may be made of Ni, for example. In the present embodiment, the second plating layer 363 is formed by electroplating. The material and method for forming the second plating layer 363, however, are not limited. In addition, the presence of the second plating layer 363 is optional. Each electrode terminal 36 has a bonding surface 365. The bonding surface 365 faces away from the corresponding electrode 34 (and faces the conductive member 1). The bonding surface 365 is bonded to a metal layer 6 formed on the conductive member 1 via a bonding portion 5.

The electrode terminals 36 electrically connected to the leads 10, 20, or 27 of the conductive member 1 are electrically connected to the switching circuit 321 included in the semiconductor layer 32. Hence, the leads 10, 20, and 27 are electrically connected to the switching circuit 321. As shown in FIGS. 3, 9, and 11 for example, at least one electrode terminal 36 overlaps with the reverse surface 202 of each lead 20 as viewed in the z direction. In the illustrated example, three electrode terminals 36 overlap with the reverse surface 202 of each lead 20 as viewed in z direction. Each electrode terminal 36 electrically connected to any of the leads 25 and 26 of the conductive member 1 is electrically connected to the control circuit 322 formed in the semiconductor layer 32. Hence, the leads 25 and 26 are electrically connected to the control circuit 322.

As shown in FIG. 2 by broken lines, the electrode terminals 36 are circular as viewed in the z direction, and the bonding surfaces 365 of electrode terminals 36 are also circular as viewed in the z direction. Each bonding surface 365 has a diameter measuring, but not limited to, 100 μm, for example. The shape and dimensions of the electrode terminals 36 as viewed in the z direction are not specifically limited. For example, the electrode terminals 36 may be oval, rectangular, or polygonal as viewed in the z direction. In addition, the shape or dimensions of one or more electrode terminals 36 may differ from those of other electrode terminals 36.

As shown in FIG. 3, each of the leads 10, 20, 25, 26, and 27 includes one or more metal layers 6. The metal layers 6 are disposed at the locations corresponding to the locations of the electrode terminals 36 of the semiconductor element 30. Each metal layer 6 has an electrode terminal 36 of the semiconductor element 30 bonded thereto. Each metal layer 6 as viewed in the z direction is circular corresponding to the shape of the bonding surface 365 of the electrode terminal 36. The metal layer 6 has a diameter greater than that of the bonding surface 365. As viewed in the z direction, the electrode terminal 36 (the bonding surface 365) is encompassed by the metal layer 6. As shown in FIGS. 12 and 13, each metal layer 6 is disposed between the conductive member 1 and an electrode terminal 36, and the electrode terminal 36 is bonded to the metal layer 6 via a bonding portion 5. The metal layer 6 inhibits chemical reaction between the conductive member 1 and the bonding portion 5 and serves to restricts the spreading area of a material forming the bonding portion 5 in the process of bonding the semiconductor element 30. In the present embodiment, the metal layers 6 include a plurality of metal layers 6A and a plurality of metal layers 6B. The metal layers 6A are formed on the lead 10A or the lead 20A. The metal layers 6B are formed on the conductive member 1 other than the lead 10A. The lead 20A have both the metal layers 6A and 6B.

As shown in FIG. 3, each metal layer 6B is formed on the obverse surface 101 of a lead 10, the obverse surface 201 of a lead 20, the obverse surface 251 of a lead 25, the obverse surface 261 of a lead 26, or the obverse surface 271 of the lead 27. As viewed in the z direction, each metal layer 6B is encompassed by the corresponding one of the obverse surfaces 101, 201, 251, 261, and 271. As shown in FIG. 12, in addition, each metal layer 6B includes a first metal layer 601. The first metal layer 601 includes a first layer 61, a second layer 62, and a third layer 63. The first layer 61 is disposed in contact with the corresponding one of the obverse surfaces 101, 201, 251, 261, and 271. In the present embodiment, since the conductive member 1 contains Cu and the bonding portion 5 contains Sn, the first layer 61 may be made of Ni, for example. The second layer 62 is disposed in contact with the first layer 61. The second layer 62 is made of, but not limited to, a material containing Pd, for example. The third layer 63 is disposed in contact with the second layer 62. The third layer 63 is made of a material that is relatively highly wettable by the bonding portion 5 (solder). The third layer 63 is made of, but not limited to, a material containing Au, for example. Note that the number of layers and the materials of the respective layers forming the first metal layer 601 are not limited. The thickness (the dimension in the z direction) of the first metal layer 601 may be, but not limited to, about 5 to 10 μm.

As shown in FIG. 3, each metal layer 6A is formed either on the lead 10A or on the lead 20A. Each metal layer 6A is not completely surrounded by the lead 10A or 20A as viewed in the z direction. In the present embodiment, each metal layer 6A formed on the lead 10A partly extends beyond the lead 10A toward the y2 side in the y direction. Similarly, each metal layer 6A formed on the lead 20A partly extends beyond the lead 20A toward the y1 side in the y direction. That is, each metal layer 6A formed on the lead 10A and each metal layers 6A formed on the lead 20A are arranged to be closer to each other in the y direction. Each metal layer 6A includes a metal-layer overhanging portion 6Aa not overlapping with the lead 10A (20A) but sticking out from the lead 10A (20A) as viewed in the z direction. The metal-layer overhanging portion 6Aa does not overlap with the body 11 of the lead 10A (or the body 21 of the lead 20A). As shown in FIG. 13, each metal layer 6A is in contact with the top surface (the surface facing toward the z2 side in the z direction) of the protrusion 12 of the lead 10A or the top surface (the surface facing toward the z2 side in the z direction) of the protrusion 22 of the lead 20A and is spaced apart from the obverse surface 101 or 201.

As shown in FIG. 13, each metal layer 6A includes a first metal layer 601 and a second metal layer 602. The first metal layer 601 is similar in configuration to the first metal layer 601 of each metal layer 6B and includes a first layer 61 in contact with the second metal layer 602. The second metal layer 602 is disposed in contact with the top surface of the protrusion 12 or 22. As viewed in the z direction, the second metal layer 602 encompasses the first metal layer 601. The configuration of the second metal layer 602 is not limited. For example, the second metal layer 602 may be similar in configuration to the first metal layer 601 and thus include a first layer 61, a second layer 62, and a third layer 63. The thickness (the dimension in the z direction) of the second metal layer 602 may be, but not limited to, about 1 to 10 μm.

For the metal layers 6A, the second metal layers 602 are formed on the regions of the lead frame that will be formed into the lead 10A and the lead 20A. Subsequently, processing such as etching is performed to form the lead 10A having the body 11 and the protrusion 12 and the lead 20A having the body 21 and the protrusion 22. In this state, only a portion of each second metal layer 602 is supported on the protrusion 12 or 22, and the rest of the second metal layer 602 sticks out from the body 11 or 21. Then, the first metal layers 601 are deposited on the predetermined regions of the lead frame. Some of the first metal layers 601 are deposited on the second metal layers 602, and such a first metal layer 601 and a second metal layer 602 together form a metal layer 6A. Some of the first metal layers 601 are deposited directly on the lead frame, and such a first metal layer 601 forms a metal layer 6B. Note that the method of forming the metal layers 6A and 6B is not limited.

As shown in FIG. 13, each electrode terminal 36 bonded to a metal layer 6A (hereinafter, “electrode terminal 36A”) is not encompassed by the lead 10A or 20A as viewed in the z direction. In the present embodiment, each electrode terminal 36A electrically connected to the lead 10A extends beyond the lead 10A toward the y2 side in the y direction. Additionally, each electrode terminal 36A electrically connected to the lead 20A extends beyond the lead 20A toward the y1 side in the y direction. That is, each electrode terminal 36A electrically connected to the lead 10A and each electrode terminal 36A electrically connected to the lead 20A are arranged to be closer to each other in the y direction. The bonding surface 365 of each electrode terminal 36A includes an overhanging portion 365a not overlapping with the lead 10A (20A) as viewed in the z direction. The overhanging portion 365a does not overlap with the body 11 of the lead 10A (or the body 21 of the lead 20A). The area of the overhanging portion 365a is not limited to a specific size, but at least 10% and at most 50% of the area of the bonding surface 365 or so may be desirable. As viewed in the z direction, the overhanging portions 365a of the respective electrode terminal 36A electrically connected to the lead 10A or 20A are located between the lead 10A and the lead 20A.

In the present embodiment, the electrode terminals 36A electrically connected to the lead 10A and the electrode terminals 36A electrically connected to the lead 20A are bonded to different electrodes 34 spaced apart from each other. The switching circuit 321 in the semiconductor layer 32 includes a switching element formed between an electrode 34 electrically connected to the lead 10A and an electrode 34 electrically connected to the lead 20A as viewed in the z direction. The first terminal (drain terminal) of the switching element is electrically connected to the lead 10A via the wiring layer, the electrode 34, and the electrode terminal 36A. The second terminal (source terminal) of the switching element is electrically connected to the lead 20A via the wiring layer, the electrode 34, and the electrode terminal 36A. The shorter the distance between the electrode 34 electrically connected to the lead 10A and the electrode 34 electrically connected to the lead 20A is, the shorter the current path formed in the wiring layer electrically connected to the switching element.

The bonding portions 5 are electrically conductive. Each bonding portion 5 is interposed between an electrode terminal 36 and a metal layer 6 and electrically connecting the electrode terminal 36 and the metal layer 6. In the present embodiment, the bonding portions 5 are made of solder containing Sn (such as SnAg), for example, but the material of the bonding portions 5 is not limited. For example, the bonding portions 5 may be made of other conductive materials, including Ag paste and sintered metal (sintered Ag). In the present embodiment, each bonding portion 5 has a frustoconical shape, with the upper surface in contact with the bonding surface 365 and the lower surface in contact with the metal layer 6. The shape of the bonding portions 5, however, is not limited.

The bonding portions 5 are formed in advance by electroplating. The bonding portions 5 as formed are in contact with the respective bonding surfaces 365 of the electrode terminals 36 of the semiconductor element 30. The semiconductor element 30 is bonded to the conductive member 1 by flip-chip mounting. Specifically, in the state where the bonding portions 5 are melted by reflowing, the semiconductor element 30 is moved toward the conductive member 1 with the element obverse surface 30a facing the conductive member 1. This brings the respective bonding portions 5, which are in a molten state, into contact with the first metal layers 601 of the metal layers 6. The third layer 63 of each first metal layer 601 is relatively highly wettable by solder. This allows each bonding portion 5 to spread over the first metal layer 601 without flowing out of the first metal layer 601 as viewed in the z direction. As a result, each bonding portion 5 forms a frustoconical shape whose cross section orthogonal to the z direction is larger with approach toward the metal layer 6 from the electrode terminal 36 in the z direction. Each bonding portion 5 is then cooled to solidify, thereby joining the electrode terminal 36 and the metal layer 6.

The sealing resin 40 covers the entire semiconductor element 30 and portions of each of the leads 10, 20, 25, 26, and 27. The sealing resin 40 may be made of a material containing a black epoxy resin, but the material of the sealing resin 40 is not limited. The sealing resin 40 is rectangular as viewed in the z direction and has a top surface 41, a bottom surface 42, a first side surface 431, a second side surface 432, a third side surface 433, and a fourth side surface 434 as shown in FIGS. 5 to 8.

As shown in FIGS. 9 to 11, the top surface 41 faces the same side as the obverse surface 101 of the lead 10 in the z direction. The bottom surface 42 faces away from top surface 41. As shown in FIGS. 4 and 9 to 11, at the bottom surface 42, the reverse surfaces of the leads are exposed, namely the reverse surfaces 102 of the leads 10, the reverse surfaces 202 of the leads 20, the reverse surfaces 252 of the leads 25, the reverse surfaces 262 of the leads 26, and the reverse surfaces 272 of the lead 27.

As shown in FIGS. 7 and 8, the first side surface 431 is connected to both the top surface 41 and the bottom surface 42 and faces the x2 side in the x direction. The second side surface 432 is connected to both the top surface 41 and the bottom surface 42 and faces the x1 side in the x direction. The first side surface 431 and the second side surface 432 are spaced apart from each other in the x direction. As shown in FIGS. 5, 6, 10, and 11, one end surface 104 of each lead 10, one end surface 204 of each lead 20, and the end surfaces 264 of a subset of the leads 26 are exposed at the first side surface 431 and flush with the first side surface 431. The other end surface 104 of each lead 10, the other end surface 204 of each lead 20, and the end surfaces 264 of a subset of the leads 26 are exposed at the second side surface 432 and flush with the second side surface 432.

As shown in FIGS. 5 and 6, the third side surface 433 is connected to the top surface 41, the bottom surface 42, the first side surface 431, and the second side surface 432, and faces the y1 side in the y direction. The fourth side surface 434 is connected to the top surface 41, the bottom surface 42, the first side surface 431, and the second side surface 432 and faces the y2 side in the y direction. The third side surface 433 and the fourth side surface 434 are spaced apart from each other in the y direction. As shown in FIGS. 7 to 9, the end surfaces 254 of the leads 25 are exposed at the third side surface 433 and flush with the third side surface 433. The end surfaces 274 of the lead 27 are exposed at the fourth side surface 434 and flush with the fourth side surface 434.

The following describes the operation and effect of the semiconductor device A10.

According to the present embodiment, each electrode terminal 36A electrically connected to the lead 10A extends beyond the lead 10A toward the y2 side in the y direction. Additionally, each electrode terminal 36A electrically connected to the lead 20A extends beyond the lead 20A toward the y1 side in the y direction. That is, as shown in FIG. 13, the electrode terminals 36A electrically connected to the lead 10A and the electrode terminals 36A electrically connected to the lead 20A are arranged to be closer to each other in the y direction. As compared with the electrode terminals 36 arranged not to extend beyond the lead 10A and 20A (see FIG. 12), the electrode terminals 36A are arranged to reduce the distance between an electrode 34 electrically connected to the lead 10A and an electrode 34 electrically connected to the lead 20A. Consequently, the current path in the wiring layer is made shorter. The semiconductor device A10 can therefore reduce the current path resistance.

The semiconductor device A10 according to the present embodiment includes the plurality of leads 10 extending in the x direction. The leads 10 are arranged at predetermined intervals in the y direction. Each lead 10 has an obverse surface 101 on which the semiconductor element 30 is mounted, two reverse surfaces 102 facing away from the obverse surface 101 in the z direction, and a recessed surface 103. The two reverse surfaces 102 are spaced apart across the recessed surface 103 in the x direction and are exposed at the bottom surface 42 of the sealing resin 40. The recessed surface 103 is covered with the sealing resin 40. That is, the leads 10 of the semiconductor device A10 are arranged such that the locations of the reverse surfaces 102 are distributed in both the x and y directions. This allows the heat of the semiconductor element 30 to be released from a plurality of distributed locations, so that the semiconductor device A10 can achieve uniform heat dissipation. In addition, when the semiconductor device A10 is mounted to a circuit board, each reverse surface 102 forms a joint with the circuit board. That is, the semiconductor device A10 is provided with may joints and can be mounted with higher reliability.

The semiconductor device A10 according to the present embodiment includes the plurality of leads 20 extending in the x direction. Each lead 20 is located between two leads 10 adjacent to each other in the y direction. Each lead 20 has an obverse surface 201 to which the semiconductor element 30 is mounted, a reverse surface 202 facing away from the obverse surface 201 in the z direction, and a recessed surface 203. The reverse surface 202 is located at the center of the lead 20 in the x direction and is exposed at the bottom surface 42 of the sealing resin 40. The recessed surface 203 is covered with the sealing resin 40. This arrangement serves to prevent that the reverse surfaces 102 of adjacent leads 10 are too close to each other. This arrangement also saves to prevent that the reverse surfaces 102 and 202 of the adjacent leads 10 and 20 are too close to each other. With such an efficient arrangement, the semiconductor device A10 is allowed to have a greater number of reverse surfaces 102 and 202. This is desirable for the semiconductor device A10 to achieve improved heat dissipation and improved mounting reliability. According to the present embodiment, in addition, the reverse surfaces 202 of the respective leads 20 do not overlap with any of the reverse surfaces 102 of the leads 10 as viewed in the y direction. This arrangement more reliably serves to prevent the reverse surfaces 102 and 202 of the adjacent leads 10 and 20 are too close to each other.

According to the present embodiment, in addition, each lead 10 is wider at a portion where a reverse surface 102 is present than at a portion where the recessed surface 103 is present. This allows the spacing to be reduced between each two leads 10 adjacent in the y direction across a lead 20. This is desirable for making the semiconductor device A10 more compact.

According to the present embodiment, in addition, the semiconductor element 30 is mounted on the conductive member 1 by flip-chip bonding. This allows the semiconductor device A10 to suppress the current path resistance and have a lower profile as compared with a semiconductor device having the electrodes 34 and leads connected by wires. Additionally, provided that the sealing resin 40 has the same outer size in plan view, the semiconductor device A10 allows a larger semiconductor element 30 to be mounted than a semiconductor device having the components electrically connected by wires. Provided that the semiconductor element 30 to be mounted is identical, the sealing resin 40 for the semiconductor device A10 can be smaller than that for a semiconductor device having components electrically connected by wires.

Although the present embodiment is directed to a case where each metal layer 6A is formed in the lead 10A or 20A and hence each electrode terminal 36A is bonded to the lead 10A or 20A, the present disclosure is not limited to this. The leads having the metal layers 6A and hence bonded to the electrode terminals 36A are not limited to the specific leads. Any electrode terminals 36 bonded to different leads can be configured as the electrode terminals 36A when it is desirable to arrange those electrode terminals 36 to be close to each other on the element obverse surface 30a of the semiconductor element 30. In addition, the metal layers 6 to be bonded to such electrode terminals 36A can be configured as the metal layers 6A. Although the present embodiment is directed to a case where the semiconductor element 30 is an LSI, the present disclosure is not limited to this. The type of the semiconductor element 30 is not limited. In addition, the numbers, shapes, and arrangement of the leads forming the conductive member 1 of the semiconductor device A10 are not limited either.

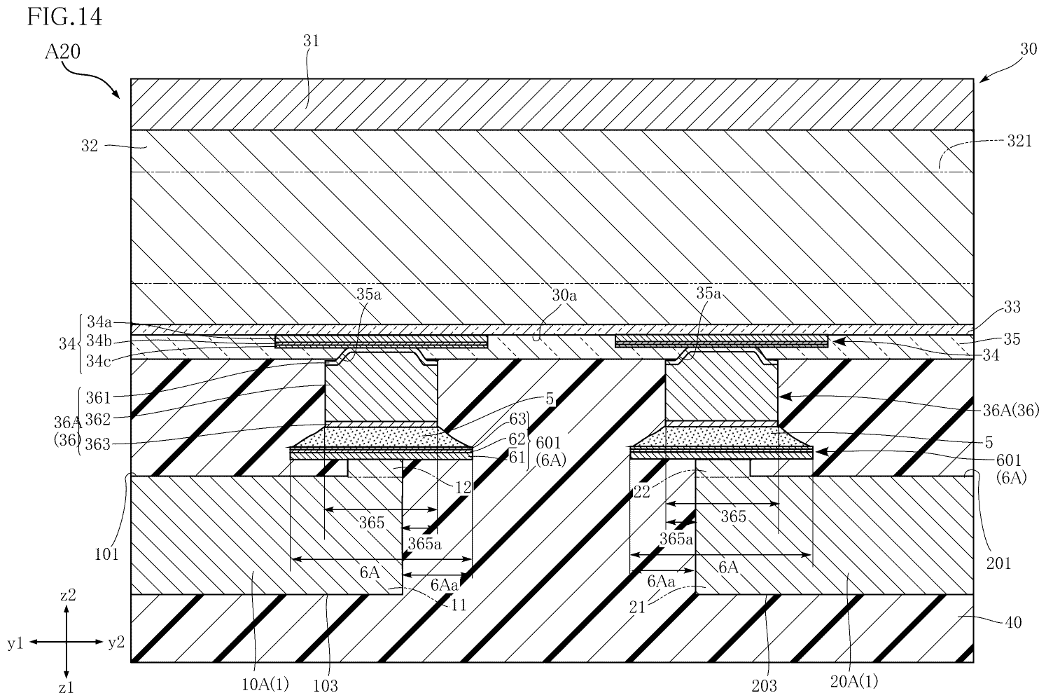

FIGS. 14 to 20 show other embodiments of the present disclosure. In these figures, components that are identical or similar to those of the above-described embodiment are given the same reference numerals as those in the above-described embodiment.

### Second Embodiment

FIG. 14 is for describing a semiconductor device A20 of a second embodiment of the present disclosure. FIG. 14 is a partially enlarged sectional view of the semiconductor device A20 and corresponds to FIG. 13. The semiconductor device A20 of the present embodiment differs from the first embodiment in that each metal layer 6A does not include a second metal layer 602. Other parts of the present embodiment are similar to those of the first embodiment in configuration and operation.

In the present embodiment, each metal layer 6A is composed of a first metal layer 601 and does not include a second metal layer 602. In other words, the metal layers 6A of the present embodiment are similar in configuration to the metal layers 6B, and the first layer 61 of each first metal layer 601 is in contact with the top surface of the protrusion 12 or 22.

Similarly to the above embodiment, each electrode terminal 36A electrically connected to the lead 10A or 20A extends beyond the lead 10A or 20A toward the other lead 10A or 20A. The electrode terminals 36A are thus closer to each other in the y direction. This arrangement reduces the distance between an electrode 34 electrically connected to the lead 10A and an electrode 34 electrically connected to the lead 20A. Consequently, the semiconductor device A20 can reduce the length of the current path formed in the wiring layer and thus reduce the current path resistance. In addition, the semiconductor device A20 has features in common with the semiconductor device A10 and thus achieves the same effect as the semiconductor device A10.

### Third Embodiment

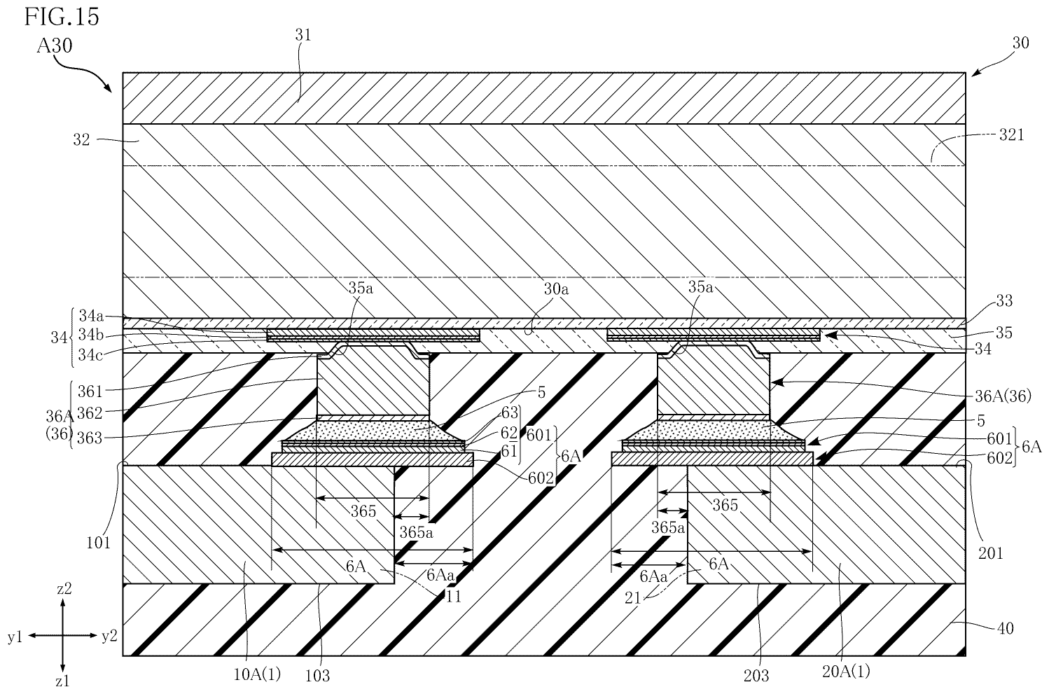

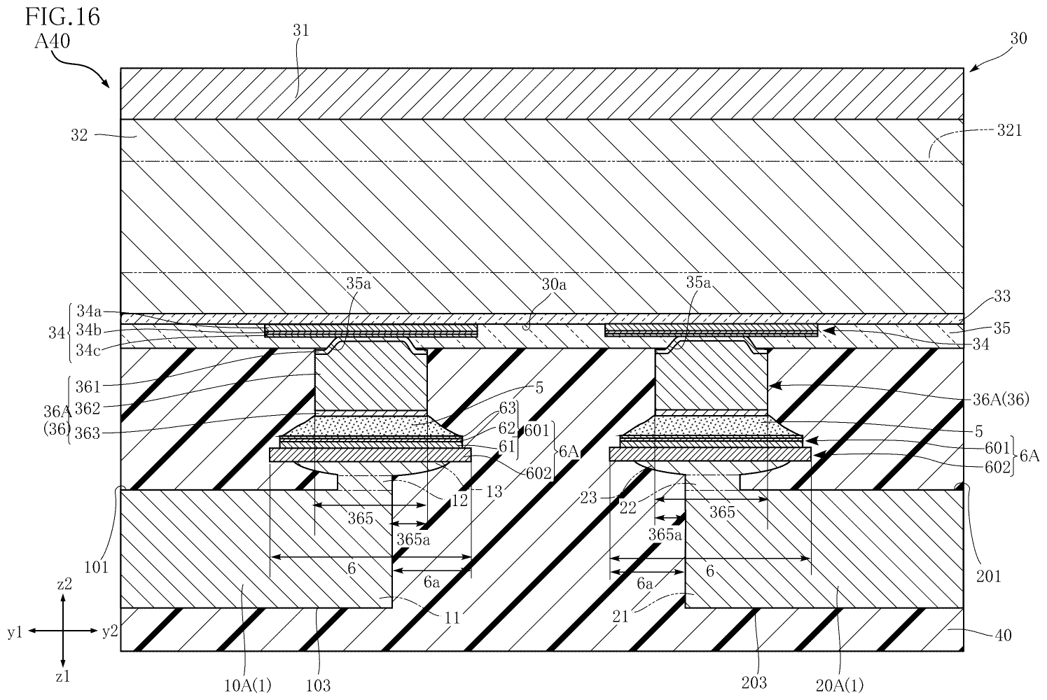

FIG. 15 is for describing a semiconductor device A30 of a third embodiment of the present disclosure. FIG. 15 is a partially enlarged sectional view of the semiconductor device A30 and corresponds to FIG. 13. The semiconductor device A30 of the present embodiment differs from the first embodiment in that the lead 10A is without the protrusion 12 and that the lead 20A is without the protrusion 22. Other parts of the present embodiment are similar to those of the first embodiment in configuration and operation. In addition, parts of the first and second embodiments may be combined in various manner.

In the present embodiment, the lead 10A does not include the protrusion 12, and each metal layer 6A is disposed in contact with the obverse surface 101. Similarly, the lead 20A does not include the protrusion 22, and each metal layer 6A is disposed in contact with the obverse surface 201.

Similarly to the above embodiment, each electrode terminal 36A electrically connected to the lead 10A or 20A extends beyond the lead 10A or 20A toward the other lead 10A or 20A. The electrode terminals 36A are thus closer to each other in the y direction. This arrangement reduces the distance between an electrode 34 electrically connected to the lead 10A and an electrode 34 electrically connected to the lead 20A. Consequently, the semiconductor device A30 can reduce the length of the current path formed in the wiring layer and thus reduce the current path resistance. In addition, the semiconductor device A30 has features in common with the semiconductor device A10 and thus achieves the same effect as the semiconductor device A10.

### Fourth Embodiment

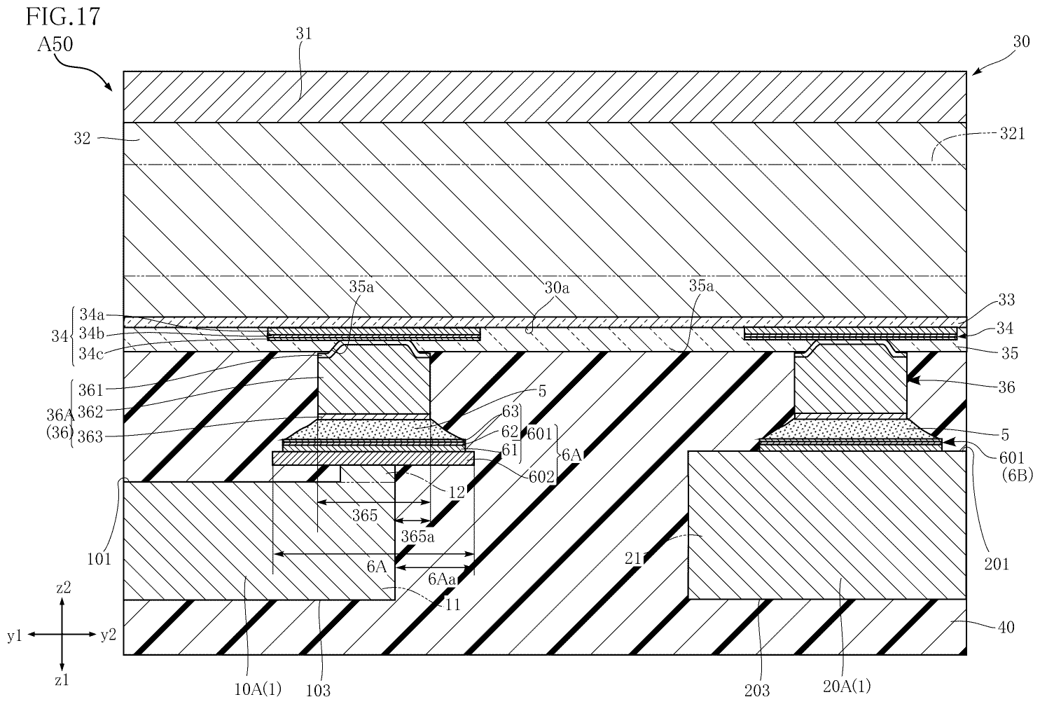

FIG. 16 is for describing a semiconductor device A40 of a fourth embodiment of the present disclosure. FIG. 16 is a partially enlarged sectional view of the semiconductor device A40 and corresponds to FIG. 13. The semiconductor device A40 of the present embodiment differs from the first embodiment in that the lead 10A additionally includes a dished portion 13, and the lead 20A additionally includes a dished portion 23. Other parts of the present embodiment are similar to those of the first embodiment in configuration and operation. In addition, parts of the first to third embodiments may be combined in various manner.

In the present embodiment, the lead 10A additionally includes a dished portion 13. The dished portion 13 is disposed between the protrusion 12 and a metal layer 6A and connected to the protrusion 12. Similarly, the lead 20A additionally includes a dished portion 23. The dished portion 23 is disposed between the protrusion 22 and a metal layer 6A and connected to the protrusion 22. The shape and dimensions of the dished portions 13 and 23 are not limited. Each metal layer 6A is disposed in contact with the surface of a dished portion 13 or 23 facing the z2 side in the z direction. The dished portions 13 and 23 are portions in contact with the metal layers 6A and thus left unremoved when the lead 10A (20A) were etched to from the protrusion 12 (22). Although the electrode terminals 36A of the present embodiment may not be said to extend beyond the lead 10A or 20A as viewed in the z direction, the electrode terminals 36A still extend beyond the body 11 or 21 as viewed in the z direction. In the present embodiment, the overhanging portion 365a of a bonding surface 365 is a region not overlapping with the body 11 of the lead 10A (or the body 21 of the lead 20A).

According to the present embodiment, each electrode terminal 36A electrically connected to the lead 10A extends beyond the body 11 of the lead 10A toward the y2 side in the y direction. Additionally, each electrode terminal 36A electrically connected to the lead 20A extends beyond the body 21 of the lead 20A toward the y1 side in the y direction. That is, each electrode terminal 36A electrically connected to the lead 10A and each electrode terminal 36A electrically connected to the lead 20A are arranged to be closer to each other in the y direction. This arrangement reduces the distance between an electrode 34 electrically connected to the lead 10A and an electrode 34 electrically connected to the lead 20A. Consequently, the semiconductor device A40 can reduce the length of the current path formed in the wiring layer and thus reduce the current path resistance. In addition, the semiconductor device A40 has features in common with the semiconductor device A10 and thus achieves the same effect as the semiconductor device A10.

### Fifth Embodiment

FIG. 17 is for describing a semiconductor device A50 of a fifth embodiment of the present disclosure. FIG. 17 is a partially enlarged sectional view of the semiconductor device A50 and corresponds to FIG. 13. The semiconductor device A50 of the present embodiment differs from the first embodiment in that the electrode terminals 36 electrically connected to the lead 20A do not extend beyond the lead 20A. Other parts of the present embodiment are similar to those of the first embodiment in configuration and operation. In addition, parts of the first to fourth embodiments may be combined in various manner.

In the present embodiment, the electrode terminals 36 electrically connected to the lead 20A are not configured as the electrode terminals 36A. In addition, the metal layers 6 formed on the lead 20A are not configured as the metal layers 6A but as the metal layers 6B. That is, the lead 20A is similar to the other leads 20 in that the electrode terminals 36 electrically connected to the lead 20A do not extend beyond the lead 20A.

In the present embodiment, each electrode terminal 36A electrically connected to the lead 10A extends beyond the lead 10A toward the y2 side in the y direction. That is, the electrode terminals 36A electrically connected to the lead 10A are arranged to be closer to the electrode terminals 36 electrically connected to the lead 20A. As compared with the arrangement in which none of the electrode terminals 36 connected to the lead 10A or 20A do not extend beyond the lead 10A or 20A (see FIG. 12), this arrangement reduces the distance between an electrode 34 electrically connected to the lead 10A and an electrode 34 electrically connected to the lead 20A. Consequently, the current path in the wiring layer is made shorter. The semiconductor device A50 can therefore reduce the current path resistance. In addition, the semiconductor device A50 has features in common with the semiconductor device A10 and thus achieves the same effect as the semiconductor device A10.

### Sixth Embodiment

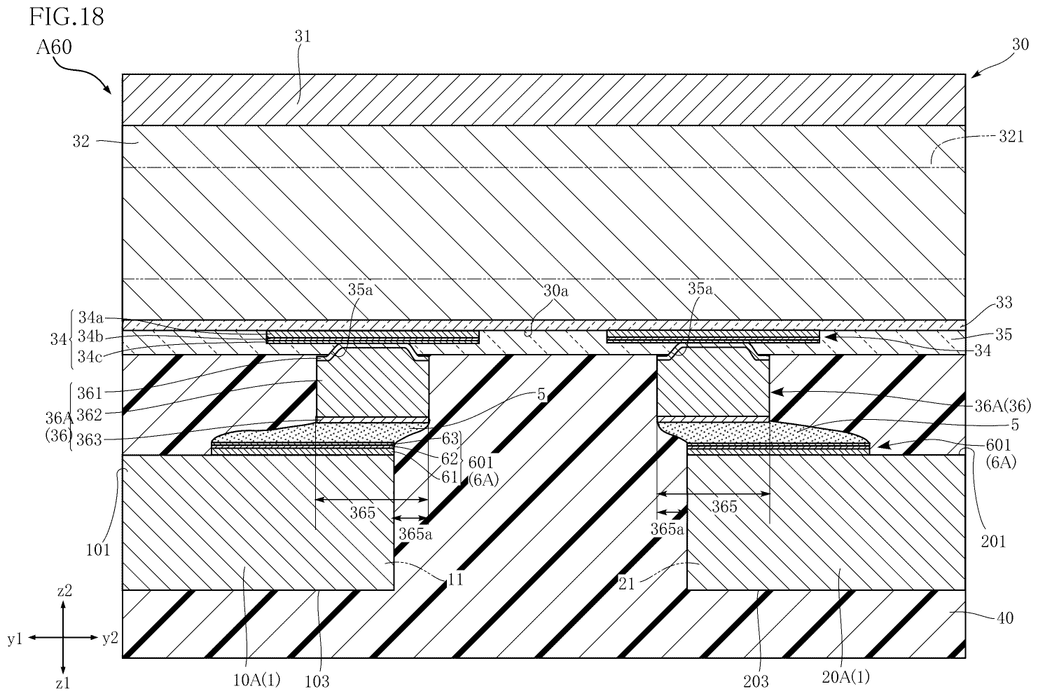

FIG. 18 is for describing a semiconductor device A60 of a sixth embodiment of the present disclosure. FIG. 18 is a partially enlarged sectional view of the semiconductor device A60 and corresponds to FIG. 13. The semiconductor device A60 of the present embodiment differs from the first embodiment in that each metal layer 6A does not extend beyond the lead 10A or 20A as viewed in the z direction. Other parts of the present embodiment are similar to those of the first embodiment in configuration and operation. In addition, parts of the first to fifth embodiments may be combined in various manner.

In the present embodiment, each metal layer 6A is composed of a first metal layer 601 and does not include a second metal layer 602. In other words, each metal layer 6A of the present embodiment are similar in configuration to the metal layers 6B. In addition, the lead 10A (20A) does not include the protrusion 12 (22), so that each metal layer 6A is disposed in contact with the obverse surface 101 (201). As viewed in the z direction, each metal layer 6A does not extend beyond the lead 10A or 20A and is encompassed by the lead 10A or 20A. The electrode terminals 36A, however, are similar to those of the first embodiment. That is, each electrode terminal 36A electrically connected to the lead 10A extends beyond the lead 10A toward the y2 side in the y each direction. Additionally, electrode terminal 36A electrically connected to the lead 20A extends beyond the lead 20A toward the y1 side in the y direction. That is, each electrode terminal 36A electrically connected to the lead 10A and each electrode terminal 36A electrically connected to the lead 20A are arranged to be closer to each other in the y direction. Each electrode terminal 36A is bonded to a corresponding metal layer 6A via a bonding portion 5.

Similarly to the above embodiment, each electrode terminal 36A electrically connected to the lead 10A or 20A extends beyond the lead 10A or 20A toward the other lead 10A or 20A and thus to be closer to each other in the y direction. This arrangement reduces the distance between an electrode 34 electrically connected to the lead 10A and an electrode 34 electrically connected to the lead 20A. Consequently, the semiconductor device A60 can reduce the length of the current path formed in the wiring layer and thus reduce the current path resistance. In addition, the semiconductor device A60 has features in common with the semiconductor device A10 and thus achieves the same effect as the semiconductor device A10.

Although the present embodiment is directed to a case where the metal layers 6A are formed on the leads 10A and 20A, the present disclosure is not limited to this. For example, the lead 10A may be without the metal layers 6A, and each electrode terminal 36A may be bonded to the obverse surface 101 of the lead 10A via a bonding portion 5. Similarly, the lead 20A may be without the metal layers 6A, and each electrode terminal 36A may be bonded to the obverse surface 201 of the lead 20A via a bonding portion 5.

### Seventh Embodiment

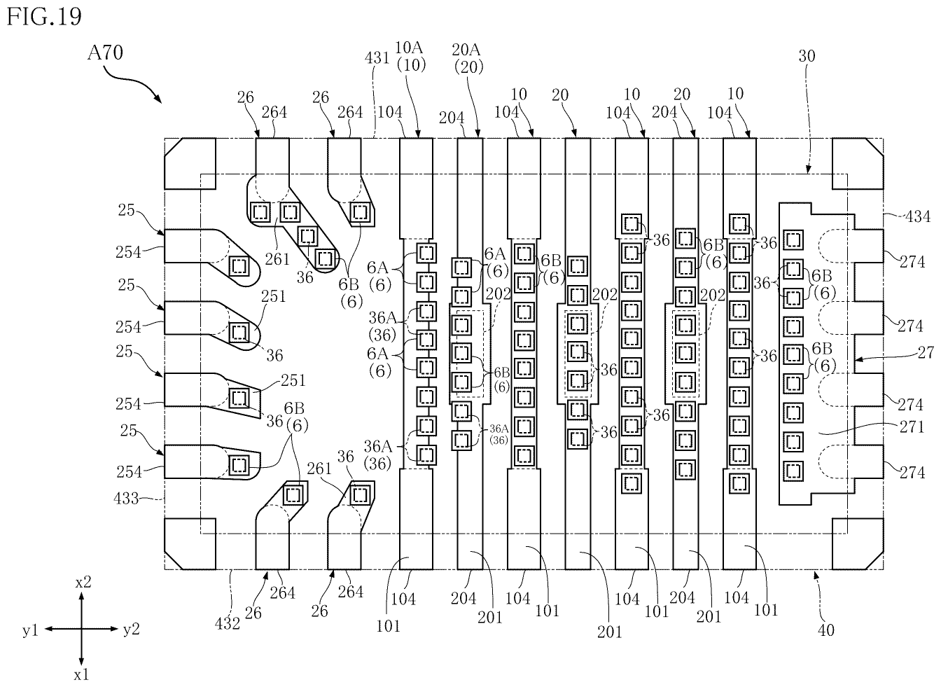

FIG. 19 is for describing a semiconductor device A70 of a seventh embodiment of the present disclosure. FIG. 19 is a plan view of the semiconductor device A70 and corresponds to FIG. 3. For convenience of description, FIG. 19 shows the sealing resin 40 and the semiconductor element 30 as transparent, and the outlines of the sealing resin 40 and the semiconductor element 30 are indicated by imaginary lines (two-dot-dash lines). The semiconductor device A70 of the present embodiment differs from the first embodiment in the shapes of the electrode terminals 36 and the metal layers 6. Other parts of the present embodiment are similar to those of the first embodiment in configuration and operation. In addition, parts of the first to sixth embodiments may be combined in various manner.

In the present embodiment, each electrode terminal 36 is rectangular as viewed in the z direction. Accordingly, the bonding surface 365 of each electrode terminal 36 has the same rectangular shape. Each metal layer 6 also has a rectangular shape as viewed in the z direction, corresponding to the shape of the bonding surface 365 of the electrode terminal 36.

Similarly to the above embodiment, each electrode terminal 36A electrically connected to the lead 10A or 20A extends beyond the lead 10A or 20A toward the other lead 10A or 20A and thus to be closer to each other in the y direction. This arrangement reduces the distance between an electrode 34 electrically connected to the lead 10A and an electrode 34 electrically connected to the lead 20A. Consequently, the semiconductor device A70 can reduce the length of the current path formed in the wiring layer and thus reduce the current path resistance. In addition, the semiconductor device A70 has features in common with the semiconductor device A10 and thus achieves the same effect as the semiconductor device A10. The shape and dimensions of the electrode terminals 36 as viewed in the z direction are not specifically limited. For example, the electrode terminals 36 may be oval, rectangular, or polygonal as viewed in the z direction. In addition, the shape or dimensions of one or more electrode terminals 36 may differ from those of other electrode terminals 36.

### Eighth Embodiment

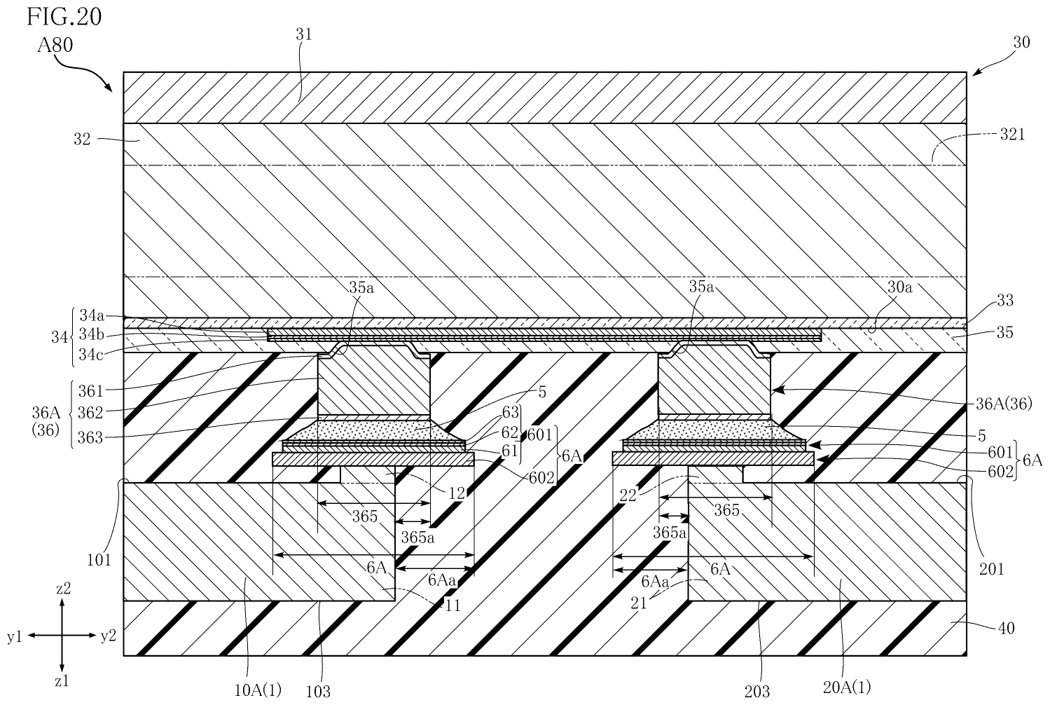

FIG. 20 is for describing a semiconductor device A80 of an eighth embodiment of the present disclosure. FIG. 20 is a partially enlarged sectional view of the semiconductor device A80 and corresponds to FIG. 13. The semiconductor device A80 of the present embodiment differs from the first embodiment in that an electrode terminal 36 electrically connected to the lead 10A and an electrode terminal 36 electrically connected to the lead 20A are electrically connected to the same electrode 34. Other parts of the present embodiment are similar to those of the first embodiment in configuration and operation. In addition, parts of the first to seventh embodiments may be combined in various manner.

The semiconductor device A80 includes a semiconductor element 30 that differs from the semiconductor element 30 of the semiconductor device A10 in the internal configuration and the shape and arrangement of the conductive member 1. In the present embodiment, the lead 10A and the lead 20A are electrically connected to each other via an electrode 34 of the semiconductor element 30. That is, an electrode terminal 36 electrically connected to the lead 10A and an electrode terminal 36 electrically connected to the lead 20A are in contact with and thus electrically connected to the same electrode 34.

Similarly to the above embodiment, each electrode terminal 36A electrically connected to the lead 10A or 20A extends beyond the lead 10A or 20A toward the other lead 10A or 20A and thus to be closer to each other in the y direction. This allows an electrode terminal 36 electrically connected to the lead 10A and an electrode terminal 36 electrically connected to the lead 20A to be placed in contact with an electrode 34 in a manner that the distance between the two contact points on the electrode 34 is smaller. Consequently, the semiconductor device A80 can reduce the length of the current path formed in the wiring layer and thus reduce the current path resistance. In addition, the semiconductor device A80 has features in common with the semiconductor device A10 and thus achieves the same effect as the semiconductor device A10.

The semiconductor device according to the present disclosure is not limited to the foregoing embodiments. Various design changes may be made freely in the specific structure of each part of the semiconductor device according to the present disclosure. The present disclosure includes embodiments described in the following clauses.

Clause 1.

A semiconductor device comprising:
a semiconductor element (30) including an element obverse surface (30a) and an element reverse surface (30b) facing away from each other in a thickness direction, an electrode layer formed on the element obverse surface, and an electrode terminal (36A) in contact with the electrode layer and protruding in the thickness direction;
a first lead (10A) electrically connected to the semiconductor element and including a first obverse surface (101) and a first reverse surface (102) facing away from each other in the thickness direction; and
a sealing resin (40) covering the semiconductor element,
wherein the first lead includes a first body (11) located on a side toward the first reverse surface with respect to the first obverse surface,
the electrode terminal includes a bonding surface (365) facing the first lead, and
the bonding surface includes an overhanging portion (365a) not overlapping with the first body as viewed in the thickness direction.

Clause 2.

The semiconductor device according to Clause 1, wherein the overhanging portion does not overlap with the first lead as viewed in the thickness direction.

Clause 3.

The semiconductor device according to Clause 1 or 2, wherein the overhanging portion has an area that is at least 10% and at most 50% of an area of the bonding surface.

Clause 4.

The semiconductor device according to any one of Clauses 1 to 3, further comprising a metal layer (6A) formed on the first lead, wherein the electrode is bonded to the metal layer.

Clause 5.

The semiconductor device according to Clause 4, wherein the metal layer includes a metal-layer overhanging portion (6Aa) not overlapping with the first body as viewed in the thickness direction.

Clause 6.

The semiconductor device according to Clause 4 or 5, wherein the metal layer includes a first metal layer (601) and a second metal layer (602),
the second metal layer is in contact with the first lead, and
the first metal layer is in contact with the second metal layer and is encompassed by the second metal layer as viewed in the thickness direction.

Clause 7.

The semiconductor device according to any one of Clauses 4 to 6, wherein the metal layer is rectangular as viewed in the thickness direction, and the bonding surface is circular.

Clause 8. (Third embodiment, FIG. 15)

The semiconductor device according to any one of Clauses 4 to 7, wherein the metal layer is disposed in contact with the first obverse surface.

Clause 9.

The semiconductor device according to any one of Clauses 4 to 7, wherein the first lead includes a protrusion (12) protruding from the first obverse surface in the thickness direction and overlapping with the bonding surface as viewed in the thickness direction, and
the metal layer is disposed in contact with the protrusion.

Clause 10.

The semiconductor device according to any one of Clauses 1 to 9, further comprising a bonding portion (5) interposed between the bonding surface and the first lead,
wherein the bonding portion comprises solder.

Clause 11.

The semiconductor device according to any one of Clauses 1 to 10, further comprising a second lead (20A) spaced apart from the first lead and electrically connected to the semiconductor element, the second lead including a second obverse surface (201) and a second reverse surface (202) facing away from each other in the thickness direction,
wherein the second lead includes a second body (21) located on a side toward the second reverse surface with respect to the second obverse surface,
the semiconductor element includes a second electrode terminal (36A) in contact with the electrode layer and protruding in the thickness direction,
the second electrode terminal includes a second bonding surface (365) facing the second lead, and
the second bonding surface includes a second overhanging portion (365a) not overlapping with the second body as viewed in the thickness direction.

Clause 12.

The semiconductor device according to Clause 11, wherein the overhanging portion and the second overhanging portion are located between the first lead and the second lead as viewed in the thickness direction.

Clause 13.

The semiconductor device according to Clause 11 or 12, wherein the electrode layer includes a first electrode (34) and a second electrode (34) spaced apart from each other,
the electrode terminal is in contact with the first electrode,
the second electrode terminal is in contact with the second electrode, and
the first electrode and the second electrode are electrically connectible within the semiconductor element.

Clause 14.

The semiconductor device according to Clause 13, wherein the semiconductor element includes a switching element including a first terminal, a second terminal, and a control terminal,
the first electrode is electrically connected to the first terminal of the switching element, and
the second electrode is electrically connected to the second terminal of the switching element.

Clause 15. (Eighth embodiment, FIG. 20)

The semiconductor device according to Clause 11 or 12, wherein the electrode layer includes a first electrode (34), and
the electrode terminal and the second electrode terminal are in contact with the first electrode.

REFERENCE NUMERALS

| | |
|---|---|
| A10, A20, A30, A40, A50, A60, | |
| A70, A80: Semiconductor device | |
| 1: Conductive member | 10, 10A: Lead |
| 101: Obverse surface | 102: Reverse surface |
| 103: Recessed surface | 104: End surface |
| 11: Body | 12: Protrusion |
| 13: Dished portion | 20, 20A: Lead |
| 201: Obverse surface | 202: Reverse surface |
| 203: Recessed surface | 204: End surface |
| 21: Body | 22: Protrusion |
| 23: Dished portion | 25: Lead |
| 251: Obverse surface | 252: Reverse surface |
| 254: End surface | 26: Lead |
| 261: Obverse surface | 262: Reverse surface |
| 264: End surface | 27: Lead |
| 271: Obverse surface | 272: Reverse surface |
| 273: Recessed surface | 274: End surface |
| 30: Semiconductor element | 30a: Element obverse surface |
| 30b: Element reverse surface | 31: Semiconductor substrate |
| 32: Semiconductor layer | 321: Switching circuit |
| 322: Control circuit | 33: Passivation film |
| 34: Electrode | 34a: First layer |
| 34b: Second layer | 34c: Third layer |
| 35: Insulating layer | 35a: Opening |
| 36, 36A: Electrode terminal | 361: Seed layer |
| 362: First plating layer | 363: Second plating layer |
| 365: Bonding surface | 365a: Overhanging portion |
| 5: Bonding portion | 40: Sealing resin |
| 41: Top surface | 42: Bottom surface |
| 431: First side surface | 432: Second side surface |
| 433: Third side surface | 434: Fourth side surface |
| 6, 6A, 6B: Metal layer | 6Aa: Metal-layer overhanging portion |
| 601: First metal layer | 61: First layer |
| 62: Second layer | 63: Third layer |
| 602: Second metal layer | |

1. A semiconductor device comprising:
a semiconductor element including an element obverse surface and an element reverse surface facing away from each other in a thickness direction, an electrode layer formed on the element obverse surface, and an electrode terminal in contact with the electrode layer and protruding in the thickness direction;
a first lead electrically connected to the semiconductor element and including a first obverse surface and a first reverse surface facing away from each other in the thickness direction; and
a sealing resin covering the semiconductor element,
wherein the first lead includes a first body located on a side toward the first reverse surface with respect to the first obverse surface,
the electrode terminal includes a bonding surface facing the first lead, and
the bonding surface includes an overhanging portion not overlapping with the first body as viewed in the thickness direction.

2. The semiconductor device according to claim 1, wherein the overhanging portion does not overlap with the first lead as viewed in the thickness direction.

3. The semiconductor device according to claim 1, wherein the overhanging portion has an area that is at least 10% and at most 50% of an area of the bonding surface.

4. The semiconductor device according to claim 1, further comprising a metal layer formed on the first lead, wherein the electrode is bonded to the metal layer.

5. The semiconductor device according to claim 4, wherein the metal layer includes a metal-layer overhanging portion not overlapping with the first body as viewed in the thickness direction.

6. The semiconductor device according to claim 4, wherein the metal layer includes a first metal layer and a second metal layer,
the second metal layer is in contact with the first lead, and
the first metal layer is in contact with the second metal layer and is encompassed by the second metal layer as viewed in the thickness direction.

7. The semiconductor device according to claim 4, wherein the metal layer is rectangular as viewed in the thickness direction, and the bonding surface is circular.

8. The semiconductor device according to claim 4, wherein the metal layer is disposed in contact with the first obverse surface.

9. The semiconductor device according to claim 4, wherein the first lead includes a protrusion protruding from the first obverse surface in the thickness direction and overlapping with the bonding surface as viewed in the thickness direction, and
the metal layer is disposed in contact with the protrusion.

10. The semiconductor device according to claim 1, further comprising a bonding portion interposed between the bonding surface and the first lead,
wherein the bonding portion comprises solder.

11. The semiconductor device according to claim 1, further comprising a second lead spaced apart from the first lead and electrically connected to the semiconductor element, the second lead including a second obverse surface and a second reverse surface facing away from each other in the thickness direction,
wherein the second lead includes a second body located on a side toward the second reverse surface with respect to the second obverse surface,
the semiconductor element includes a second electrode terminal in contact with the electrode layer and protruding in the thickness direction,
the second electrode terminal includes a second bonding surface facing the second lead, and
the second bonding surface includes a second overhanging portion not overlapping with the second body as viewed in the thickness direction.

12. The semiconductor device according to claim 11, wherein the overhanging portion and the second overhanging portion are located between the first lead and the second lead as viewed in the thickness direction.

13. The semiconductor device according to claim 11, wherein the electrode layer includes a first electrode and a second electrode spaced apart from each other,
the electrode terminal is in contact with the first electrode,
the second electrode terminal is in contact with the second electrode, and
the first electrode and the second electrode are electrically connectible within the semiconductor element.

14. The semiconductor device according to claim 13, wherein the semiconductor element includes a switching element including a first terminal, a second terminal, and a control terminal,
the first electrode is electrically connected to the first terminal of the switching element, and
the second electrode is electrically connected to the second terminal of the switching element.

15. The semiconductor device according to claim 11, wherein the electrode layer includes a first electrode, and
the electrode terminal and the second electrode terminal are in contact with the first electrode.
